(19) United States
(12) Patent Application Publication
(10) Pub. No.: US 2010/0001378 A1
(43) Pub. Date: Jan. 7, 2010

(54) Through-substrate vias and method of fabricating same

(75) Inventors: Jeffrey F. DeNatale, Thousand Oaks, CA (US); Philip A. Stupar, Oxnard, CA (US); Alexandros P. Papavasiliou, Thousand Oaks, CA (US)

Correspondence Address: KOPPEL, PATRICK ,HEYBL & DAWSON, PLC, 2815 TOWNSGATE ROAD, SUITE 215, WESTLAKE VILLAGE, CA, 91361-5827, US

(73) Assignee: Teledyne Scientific & Imaging, LLC

(21) Appl. No.: 12/217,217

(22) Filed: Jul. 1, 2008

(51) Int. Cl. H01L 23/538; H01L 21/768

(52) U.S. Cl. 257/621; 438/667; 257/E21.597; 257/E23.174

(57) ABSTRACT

An through-substrate via fabrication method requires forming a through-substrate via hole in a semiconductor substrate, depositing an electrically insulating, continuous and substantially conformal isolation material onto the substrate and interior walls of the via using ALD, and depositing a conductive material into the via and over the isolation material using ALD such that it is electrically continuous across the length of the via hole. The isolation material may be prepared by activating it with a seed layer deposited by ALD. The via hole is preferably formed by dry etching first and second cavities having respective diameters into the substrate's top and bottom surfaces, respectively, to form a single continuous aperture through the substrate. The present method may be practiced at temperatures of less than 200° C. The basic fabrication method may be extended to provide vias with multiple conductive layers, such as coaxial and triaxial vias.

### FIELD OF THE INVENTION

This invention is directed to a method for fabricating high aspect ratio through-substrate vias.

### BACKGROUND

The fabrication of integrated circuit (IC) chips has become a sophisticated process that can allow complex circuitry to be densely packaged onto a single substrate or wafer. Originally, most chips were fabricated in a simple planar design. However, planar chip designs limit the amount of circuitry that can be placed on a single substrate.

To overcome some of the limitations resulting from the planar design, designers began stacking chips to form three-dimensional designs. Vias extending through the substrate—i.e., “through-substrate vias”—create three-dimensional interconnects which facilitate connection to the circuitry throughout the chip, thereby allowing the implementation of more advanced circuits and enabling a higher density of complex circuitry to be placed within a given die area. Furthermore, a three-dimensional design with through-substrate vias can enable advanced micro-electronic chip stacking, which can result, for example, in increased processing power for image data and signal processing.

Although three-dimensional chips using through-substrate vias have proven useful, they are currently limited. In one approach, through-substrate vias have been formed in thick substrates—e.g., 200-400 μm; the thickness enables the substrates to retain mechanical durability and to be easily handled and processed without the need for sequential stacking and thinning operations. Using this approach, substrates are etched and the formed vias are electrically insulated and metallized.

Although this approach provides some advantages, it introduces other limitations, such as the inability to fabricate small-diameter, fine-pitch vias. Indeed, using current etching techniques, the formation of high aspect ratio (i.e., ratio of depth to diameter) vias results in a large diameter-to-pitch (i.e., the center-to-center measurement between vias) ratio for the vias. This limits the etch depth of the vias, and also reduces the amount of available space on the substrate for other uses. Current techniques typically produce vias having diameters of about 4 μm with a depth of about 20 μm (using low temperature techniques) and 100 μm diameters with a depth of about 500 μm (using high temperature techniques); thus, an aspect ratio of about 5:1 is provided with either high or low temperature techniques. Both dry etching and wet etching have been demonstrated for the thick wafer processing, and both suffer from constraints on via size and separation. In addition, it is very difficult to reliably deposit electrical isolation layers and metallic conductors using low process temperatures in high aspect ratio vias.

To reduce via diameters, some techniques sequentially stack, bond and thin multiple wafers into a ‘single’ wafer stack and form the vias through only a single thin layer of the stacked wafers at a time, thereby reducing the aspect ratio and diameter required of an individual via. This approach involves wafer ‘thinning’, in which the wafers to be stacked are bonded and one portion (non-circuit containing, exposed surface) of the stacked wafers is thinned to reduce the wafer thickness, typically down to 10-25 μm. At this thickness, small diameter vias can be etched through the thinned layer while maintaining separation between neighboring vias. Alternatively, the via could be etched to a limited depth prior to the bonding, and then have its bottom (non-circuit containing) surface exposed in the thinning operation after bonding.

This approach can use well-developed fabrication processes; however, disadvantages arise from the need for sequential processing of each successive layer and the complexity of intermediate testing. Further, the thinning of the stacked wafers reduces their integrity and makes them more susceptible to breakage during use and damage from handling. Further still, many current bonding techniques involve high temperatures, high voltage and/or high pressure, each of which poses difficulties if the stacking includes prefabricated integrated circuits with multi-level interconnects. Further, in this approach sequential circuit wafers can only be stacked in one orientation, with active circuitry at the bond interface, since the thinning process must only remove unprocessed substrate. Finally, the wafer-level sequential stacking can introduce stacked device yield impacts resulting from the random alignment of defects in a die from one layer with a good die in another, reducing operability at the stack level.

In addition to a hole that passes completely through a substrate, a through-substrate via generally also requires an insulating layer lining the inner surfaces of the hole, and a conductive layer over the insulating layer. For a high aspect ratio via having a narrow diameter, it can be difficult to provide these insulating and conductive layers. One technique for forming such a via is described in co-pending patent application Ser. No. 11/167,014 to Borwick et al. and assigned to the present assignee. Here, wet processing is used to provide the via's sidewall seed layer and conductive layer. However, it can be difficult to achieve uniform seed layer coverage using wet processing, and particulates in the liquid solution can clog the vias, particularly those having a small diameter.

### SUMMARY OF THE INVENTION

A through-substrate via fabrication method is presented which overcomes the problems noted above, providing high aspect ratio through-substrate vias with a process that eliminates problems associated with wet processing.

The present method fabricates through-substrate vias through a semiconductor substrate which may contain active circuitry. The method requires first forming a through-substrate via hole in a semiconductor substrate. An isolation material which is electrically insulating, continuous and substantially conformal is then deposited directly onto the substrate and onto the interior walls of the via hole using atomic layer deposition (ALD). A basic via is completed by depositing a conductive material into the via hole and over the isolation material using ALD, such that the conductive material is electrically continuous across the length of the via hole. The fabrication method may further comprise preparing the isolation material by activating it with a seed layer which reacts with the conductive material, with the seed layer deposited by ALD.

The method enables the fabrication of through-substrate via holes having depths of greater than 100 μm. The through-substrate via hole is preferably formed by dry etching a first cavity having a first diameter into the substrate's first surface, and dry etching a second cavity having a second diameter into the substrate's second surface, such that the first and second cavities form a single continuous aperture through the substrate.

The present method may be successfully practiced at temperatures of less than 200° C., thereby avoiding damage to circuitry residing on the substrate that might otherwise occur. The basic fabrication method may be extended to form shielded or coaxial vias, triaxial vias, or vias having any desired number of conductive layers.

### BRIEF DESCRIPTION OF THE DRAWINGS

The detailed description of embodiments of the invention will be made with reference to the accompanying drawings, wherein like numerals designate corresponding parts in the figures.

FIGS. 1a-1g are sectional views of a fabrication process for forming high aspect ratio through-substrate vias in accordance with the present invention.

FIG. 2 is a sectional view of a triaxial via formed in accordance with the present fabrication process.

### DETAILED DESCRIPTION OF THE INVENTION

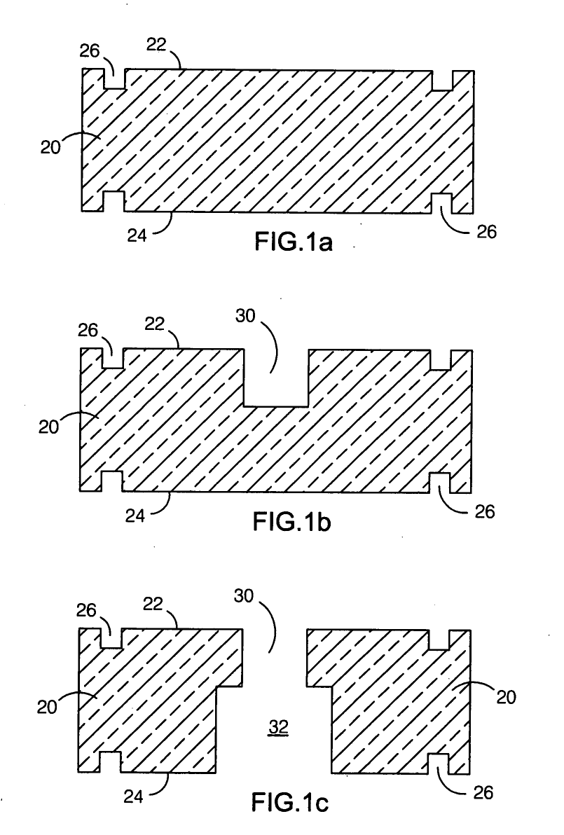

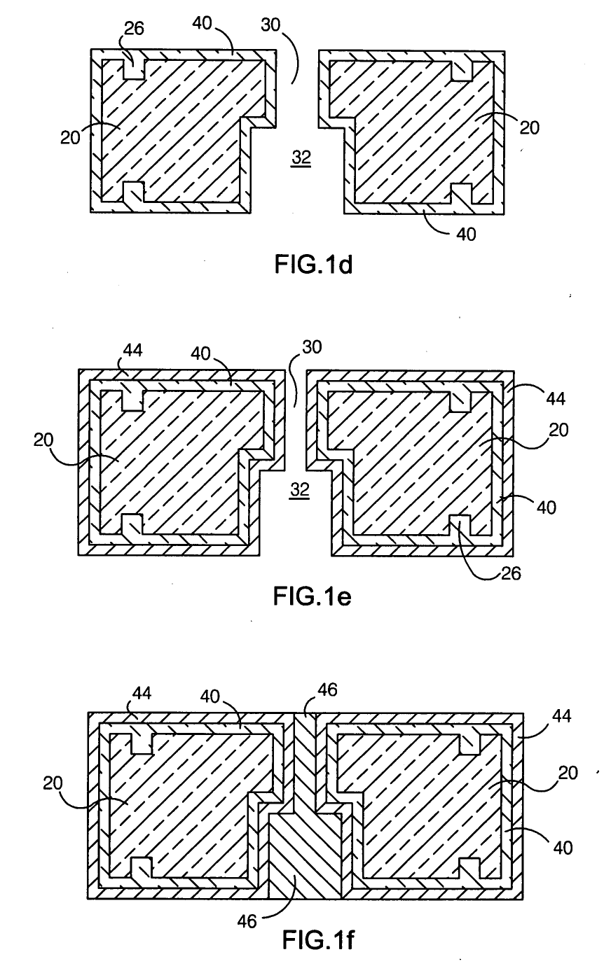

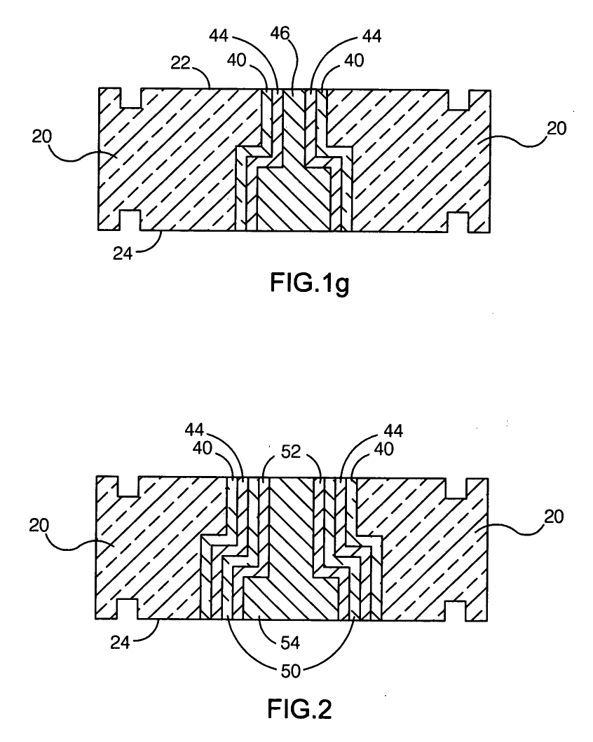

The present method is directed to a process for fabricating high aspect ratio through-substrate vias. The basic process steps are illustrated in the series of sectional views shown in FIGS. 1a-1g. In FIG. 1a, a substrate 20 has a first surface 22 and a second surface 24. Circuitry (not shown) may be disposed on first surface 22, on second surface 24, and/or between surfaces 22 and 24. The substrate may be made from any of a number of semiconductor materials, including but not limited to, silicon, gallium arsenide or indium phosphate. Alignment marks 26 may be etched on the first and second surfaces, to facilitate alignment of the substrate during subsequent process steps.

In FIG. 1b, a first cavity 30 is etched into first surface 22. The first cavity has a first diameter, and extends a first depth into the substrate. The first diameter is typically chosen to minimize the consumed circuit area on surface 22. The first depth is typically chosen to enable the first cavity to extend below the depth of any active circuitry on surface 22. Then, as shown in FIG. 1c, a second cavity 32 having a second diameter, is etched coaxially with first cavity 30 into second surface 24. The second cavity is etched to a second depth such that it communicates with first cavity 30 to form a continuous aperture through the entire thickness of the substrate. The first and second cavities preferably extend to depths in the range of 20 μm-200 μm and 100 μm-350 μm, respectively, and have diameters of 2 μm-8 μm and 6 μm-25 μm, respectively. The larger diameter of the second cavity enables a greater depth to be achieved at the same aspect ratio. This enables the continuous aperture to extend through a greater total wafer thickness while minimizing the circuit area on surface 22 consumed by the via.

The cavities are formed by dry etching, preferably using a deep reactive ion etching process (“DRIE”). A preferred DRIE process known as the Bosch process utilizes time-sequenced alternating etch and passivation steps. An etchant such as sulfur hexafluoride SF₆ is used to etch a portion of the cavity into the substrate. To passivate the side wall of the cavity and prevent further lateral etching, an insulating layer is subsequently deposited using a separate gas composition which includes a species such as octafluorocyclobutane C₄F₈. This process is repeated until the desired depth is achieved. Etching via this process allows for high selectivity and achieves substantially vertical side walls, with aspect ratios as high as 40:1 or more. This high aspect ratio facilitates the production of smaller diameter cavities and smaller via-to-via spacings, as it reduces the amount of lateral blooming during etching and reduces side wall scalloping.

In FIG. 1d, an isolation material 40 is deposited directly onto substrate 20 and onto the interior walls of the aperture using atomic layer deposition (ALD), so as to provide an isolation layer that is electrically insulating, continuous and substantially conformal. The uniform coverage of the sidewalls with isolation material 40 acts to electrically isolate the through-substrate via from the substrate, as well as from other through-substrate vias being fabricated in substrate 20.

The isolation material preferably comprises inorganic oxides capable of providing electrical insulation and conformal surface coatings; metal oxides, including the oxides of aluminum, titanium, tantalum, niobium, zirconium, hafnium, lanthanum, yttrium, cerium, silicon, scandium, chromium, and erbium, are suitable.

After the isolation material 40 has been deposited onto the substrate, an electrically conductive material 44 is deposited over the isolation material using ALD such that the conductive material is electrically continuous across the length of the via hole; this is shown in FIG. 1e. The conductive material is preferably chosen from a group consisting of nickel, palladium, platinum, ruthenium, tungsten, iridium, copper or zinc oxide. The dry etching and ALD deposition steps are preferably conducted at a temperature of less than 200° C., such that circuitry residing on the substrate, such as CMOS circuitry, is not damaged by excessive heat.

ALD is a gas phase chemical process used to create thin film coatings that are highly conformal and have extremely precise thickness control. The majority of ALD reactions use two chemicals, typically called precursors. These precursors react with a surface one-at-a-time in a sequential manner. By exposing the precursors to the growth surface repeatedly, a thin film is deposited. Additional details about ALD can be found, for example, in “Surface Chemistry for Atomic Layer Growth”, S. M. George et al., J. Phys. Chem., Vol. 100, No. 31 (1996), pp. 13121-13131.

In some cases, it may be desirable to ‘activate’ isolation material 40 prior to the deposition of conductive material 44, to make the isolation material more conducive to receiving the conductive material. This can be accomplished by depositing a seed layer (not shown) onto isolation material 40; this is preferably accomplished using ALD, which deposits a conformal seed layer uniformly on the deep-etched sidewalls of the via. A seed layer is selected which will cause a reaction with conductive material 44 when the conductive material is deposited onto the substrate; palladium is one possible seed layer material. Once isolation material 40 is activated, conductive material 44 is deposited onto the activated isolation material.

The structure of FIG. 1e provides a through-substrate via, with conduction through the via provided by conductive material 44. Preferably, any portions of cavities 30 and 32 which were not already filled by isolation material 40 and conductive material 44 are now filled with a metal 46, as shown in FIG. 1f. This hole filling is done for two reasons. First, processing of the substrate with the hole in it is difficult: photoresist materials may get sucked into the hole by vacuum chucks, and air bubbles that get trapped in the hole tend to pop and degrade the cosmetics of the subsequent surface pattern. Second, the conductive material layer 44 deposited by ALD is very thin, and hence may have a relatively high resistance. The hole is preferably filled using a plating process—preferably, an electroless plating of a material like nickel, gold, or copper; uniform electroless plating is facilitated by the uniform depositions achieved using ALD. This reduces the resistance of the center conductor and physically plugs the hole to permit resist processing. Electrolytic plating may also be used.

As illustrated in FIG. 1g, additional processing may be performed to remove the isolation and conductive layers from areas where they are not needed, but leaving the completed through-substrate via. Further, additional isolation layers and conductive metal traces may be processed on surfaces 22 and/or 24 to route the electrical interconnection points to the desired locations on the surfaces. These process steps are not shown, and use fabrication techniques well known to those skilled in semiconductor processing.

With the possible exception of the hole-filling step, the present method is an all-dry process, thereby eliminating the possibility of liquid solution particulates clogging the through-substrate vias, as may happen when using prior art techniques. Wet processing techniques may be used in the final steps of the process in FIG. 1 to plug the via, since at this stage the via is isolated and electrically continuous across its length, and thus clogging due to solution particulates does not reduce via operability. The present ALD-based process provides good control over layer thickness (typically, to within several nanometers), such that conformal coatings and high yields are reliably achieved. Furthermore, the ability to deposit both insulators and metals using ALD provides a means of forming both isolation and conductive layers in a single process operation. Note, however, that the processing time needed for the present process may be considerably longer than that required by prior art methods, but the process is compatible with batch fabrication and automated operation. Employing ALD results in all surfaces being coated with the material being deposited; as such, it is necessary to pattern and etch the substrate to remove the deposited isolation and conductive materials from areas where they are not needed. The present method enables high aspect ratio vias to be fabricated in substrates having a thickness of greater than 50 μm.

The present process can be extended to form a shielded or coaxial via. A coaxial via is shown in FIG. 2. After completing the process steps shown in FIGS. 1a-1e, a second electrically insulating, continuous and substantially conformal isolation layer 50 would be deposited by ALD, followed by the deposition by ALD of a second conductive layer 52 which is electrically continuous across the length of the via hole. Any portions of cavities 30 and 32 which were not already filled by isolation layers 40, 50 and conductive layers 44, 52 are now preferably filled with a metal 54. Additional processing steps remove the isolation and conductive layers from areas where they are not needed, leaving the completed through-substrate via as shown. Further processing would be needed to form metallization on one or both of the substrate surfaces to provide independent connections to both the center metal (54) and shield metal (44) of the coaxial via. Additional dielectric layers of adequate thickness, comprising, for example, plasma-enhanced chemical vapor deposition (PECVD) oxide, may be deposited between the two metal deposition steps (layers 44 and 52, respectively) to facilitate the processing to make independent connections to the two metal layers. This would provide an etch stop layer to permit patterning of layer 52 without exposing layer 44. Further, additional isolation layers and conductive metal traces may be processed on the device surfaces to route the electrical interconnection points to the desired locations on the surfaces. These process steps (not shown) use fabrication techniques well known to those skilled in semiconductor processing.

The present process can be extended in this way until as many conductive layers as needed are provided. For example, a triaxial via can be formed by following the process steps shown in FIGS. 1a-1e with the deposition of a second layer of isolation material over conductive material 44, the deposition of a second layer of conductive material over the second isolation material layer, the deposition of a third layer of isolation material over the second layer of conductive material, and the deposition of a third layer of conductive material over the third isolation material layer, with each deposition performed using ALD. The depositions are performed such that the second and third isolation material layers are electrically insulating, continuous and substantially conformal, and the second and third conductive material layers are electrically continuous across the length of the via hole. Any portions of cavities 30 and 32 which were not already filled by the three isolation layers and three conductive layers would preferably be filled with a metal. Additional processing steps remove the isolation and conductive layers from areas where they are not needed, and provide metallization on the substrate surfaces to provide independent connections to each of the conductive material layers of the triaxial via.

For a basic single conductor via, or a coaxial via, the dielectric constant of the isolation layer is preferably low, in order to minimize the capacitance of the interconnection provided by the via. This may not be an issue for a triaxial via, since the conductive material layer serving as the shield could be biased to a voltage that compensates for the via's capacitance.

The present process is well-suited to use with a multi-layer stack of substrates, in which a substrate containing through-substrate vias as described herein is bonded together with a plurality of additional substrates. The bonding between substrates is effected with, for example, solder bumps, indium columns, Au—Au thermocompression bonding or glue. The bonding means provides a mechanical function, and can also provide an electrical function when the bonds effect electrical interconnections between individual substrate layers. Signals may be routed from one substrate to another through vias as described herein, as well as via the bonding means.

Although the foregoing described the invention with preferred embodiments, this is not intended to limit the invention. Indeed, embodiments of this invention can be combined with other circuit chips and systems. For instance, embodiments of the invention can be used for compact electronic circuits with multiple stacking layers and circuitry. Other uses include an enhanced three-dimensional electronic imager having wide dynamic range and pixel level image processing due to the density of the vias on the wafer, RF filters, FPA ROICs, and 3D consumer electronics. Other applications include a vertically interconnected sensor array which provides signal processing in conjunction with infrared sensor systems, an arrayed acoustic sensing system, LADAR, and microprocessor circuits in which latency across the chip presents an issue.

As seen from the foregoing, substrates having high aspect ratio through-substrate vias are intended to be used as stand alone substrates or in combination with other types of substrates or systems. In this regard, the foregoing is intended to cover all modifications and alternative constructions falling within the spirit and scope of the invention as expressed in the appended claims, wherein no portion of the disclosure is intended, expressly or implicitly, to be dedicated to the public domain if not set forth in the claims.

I claim:

1. A process for fabricating a through-substrate via in a semiconductor substrate which may contain active circuitry, the substrate having a first surface and a second surface, comprising:
forming a through-substrate via hole in a semiconductor substrate;
depositing an isolation material directly onto the substrate and onto the interior walls of said through-substrate via hole using atomic layer deposition (ALD) such that said isolation material is electrically insulating, continuous and substantially conformal; and
depositing conductive material into the via hole over said isolation material using ALD such that said conductive material is electrically continuous across the length of said via hole.

2. The process of claim 1, wherein said steps of forming the via hole, depositing the isolation material, and depositing the conductive material are performed in a low temperature range.

3. The process of claim 2, wherein said low temperature range is <200° C.

4. The process of claim 1, further comprising preparing said isolation material by activating it with a seed layer which reacts with said conductive material.

5. The process of claim 4, wherein said seed layer is deposited by ALD.

6. The process of claim 1, wherein the depth of said through-substrate via hole is greater than 100 μm.

7. The process of claim 1, wherein said through-substrate via hole is formed by:
dry etching a first cavity into said substrate's first surface, said first cavity having a first diameter; and
dry etching a second cavity into said substrate's second surface, said second cavity having a second diameter, wherein the first and second cavities form a single continuous aperture through the substrate.

8. The process of claim 7, wherein said first and second cavities extend to depths in the range of 20 μm-200 μm and 100 μm-350 μm, respectively.

9. The process of claim 7, wherein said first and second diameters are in the range of 2 μm-8 μm and 6 μm-25 μm, respectively,

10. The process of claim 7, wherein said first and second cavities are dry etched using a deep reactive ion etching (DRIE) process.

11. The process of claim 10, wherein said DRIE process is the Bosch process.

12. The process of claim 7, wherein said first surface contains active circuitry and said first cavity is etched so as to have a depth which extends below the depth of the active circuitry on said first surface.

13. The process of claim 1, wherein the conductive material is chosen from a group consisting of nickel, palladium, platinum, ruthenium, tungsten, iridium, copper or zinc oxide.

14. The process of claim 1, wherein said deposition of an isolation material by ALD comprises deposition of inorganic oxides capable of providing electrical insulation and conformal surface coatings.

15. The process of claim 14, wherein said isolation material is chosen from a group of metal oxides comprising the oxides of aluminum, titanium, tantalum, niobium, zirconium, hafnium, lanthanum, yttrium, cerium, silicon, scandium, chromium, and erbium.

16. The process of claim 1, further comprising:
depositing a second layer of isolation material over said conductive material using ALD such that said second layer of isolation material is electrically insulating, continuous and substantially conformal; and
depositing a second layer of conductive material over said second layer of isolation material using ALD such that said second layer of conductive material is electrically continuous across the length of said via hole;
such that said layers of isolation material and said layers of conductive material form a shielded or coaxial via through said substrate.

17. The process of claim 16, further comprising:
depositing a third layer of isolation material over said second layer of conductive material using ALD such that said third layer of isolation material is electrically insulating, continuous and substantially conformal; and
depositing a third layer of conductive material over said third layer of isolation material using ALD such that said third layer of conductive material is electrically continuous across the length of said via hole;
such that said layers of isolation material and said layers of conductive material form a triaxial via through said substrate.

18. The process of claim 17, wherein one of said conductive material layers serves as a shield layer, further comprising biasing said shield layer to compensate for said via's capacitance.

19. The process of claim 16, further comprising depositing at least one dielectric layer between the depositions of said first and second conductive layers which provides an etch stop layer to permit patterning of said second conductive layer without exposing said first conductive layer.

20. The process of claim 1, further comprising filling any portion of said via hole not already filled by said isolation material and said conductive material with a metal.

21. The process of claim 20, wherein said via hole is filled with a metal using an electroless or an electrolytic plating process.

22. The process of claim 1, further comprising removing said isolation and conductive materials from areas of said substrate where they are not needed.

23. The process of claim 1, further comprising forming metallization on one or both of said first and second substrate surfaces to provide electrical connections to the conductive material layers of said through-substrate via.

24. A substrate having first and second surfaces, comprising:
a substantially cylindrical cavity formed into the first surface to a first depth and having a first diameter;
a substantially cylindrical cavity formed into the second surface to a second depth greater than said first depth and having a second diameter greater than or equal to said first diameter, said substantially cylindrical cavities forming a via hole through said substrate;
an isolation material deposited on said substrate and onto the interior walls of said via hole using atomic layer deposition (ALD) such that said isolation material is electrically insulating, continuous and substantially conformal; and
a conductive material deposited into the via hole over said isolation material using ALD such that said conductive material is electrically continuous across the length of said via hole, thereby forming a through-substrate via.

25. The substrate of claim 24, wherein said first diameter and said second diameter are substantially equal.

26. The substrate of claim 24, wherein said first diameter is less than said second diameter.

27. The substrate of claim 24, wherein said substrate is bonded together with a plurality of additional substrates to form a multi-layer stack of substrates.

28. The substrate of claim 27, wherein said bonding effects electrical interconnections between individual substrate layers.

29. The substrate of claim 24, further comprising circuitry on said substrate, said through-substrate via providing an electrical connection to said circuitry.

30. The substrate of claim 24, wherein said substrate has a thickness of greater than 50 μm.

31. The substrate of claim 24, further comprising:
a second layer of isolation material deposited over said conductive material using ALD such that said second layer of isolation material is electrically insulating, continuous and substantially conformal; and
a second layer of conductive material deposited over said second layer of isolation material using ALD such that said second layer of conductive material is electrically continuous across the length of said via hole;
such that said layers of isolation material and said layers of conductive material form a shielded or coaxial via through said substrate.

32. The substrate of claim 31, further comprising:
a third layer of isolation material deposited over said second layer of conductive material using ALD such that said third layer of isolation material is electrically insulating, continuous and substantially conformal; and
a third layer of conductive material deposited over said third layer of isolation material using ALD such that said third layer of conductive material is electrically continuous across the length of said via hole;
such that said layers of isolation material and said layers of conductive material form a triaxial via through said substrate.

33. The substrate of claim 32, wherein one of said conductive material layers serves as a shield layer, further comprising a voltage applied to said shield layer to compensate for said via's capacitance.

34. The substrate of claim 31, further comprising at least one dielectric layer between said first and second conductive layers, said at least one dielectric layer arranged to provide an etch stop layer to permit patterning of said second conductive layer without exposing said first conductive layer.

35. The substrate of claim 34, wherein said at least one dielectric layer comprises at least one PECVD oxide layer.

36. The substrate of claim 24, further comprising metal which fills any portion of said via hole not filled by said isolation material and said conductive material.

37. The substrate of claim 24, wherein said first surface contains active circuitry and said first depth is such that the depth of said substantially cylindrical cavity formed in said first surface extends below the depth of said active circuitry.
